(19) United States
(12) Patent Application Publication
(10) Pub. No.: US 2017/0176851 A1
(43) Pub. Date: Jun. 22, 2017

(54) METHOD FOR PRODUCING A MASK FOR THE EXTREME ULTRAVIOLET WAVELENGTH RANGE, MASK AND DEVICE

(71) Applicant: Carl Zeiss SMT GmbH, Oberkochen (DE)

(72) Inventors: Jan-Hendrik Peters, Radebeul (DE); Jörg Frederik Blumrich, Jena (DE); Anthony Garetto, Jena (DE); Renzo Capelli, Traunstein (DE)

(21) Appl. No.: 15/451,522

(22) Filed: Mar. 7, 2017

Related U.S. Application Data
(63) Continuation of application No. PCT/EP2015/069503, filed on Aug. 26, 2015.

(30) Foreign Application Priority Data
Sep. 8, 2014 (DE) 102014217907.6

(51) Int. Cl. G03F 1/72; B05D 5/00; G03F 1/22

(52) U.S. Cl. CPC G03F 1/72; G03F 1/22; B05D 5/005

(57) ABSTRACT

A method for producing a mask for the extreme ultraviolet wavelength range proceeding from a mask blank having defects is provided. The method includes classifying the defects into at least one first group and one second group; optimizing the arrangement of an absorber pattern on the mask blank in order to compensate for a maximum number of the defects of the first group by means of the arranged absorber pattern; and applying the optimized absorber pattern to the mask blank.

### CROSS-REFERENCE TO RELATED APPLICATIONS

This application is a continuation of International Application PCT/EP2015/069503, having a filing date of Aug. 26, 2016, which claims priority to German patent application 10 2014 217 907.6, filed on Sep. 8, 2014. The entire contents of the above applications are herein incorporated by reference.

### TECHNICAL FIELD

The present invention is concerned with treating defects of an EUV mask blank.

### BACKGROUND

As a consequence of the growing integration density in the semiconductor industry, photolithography masks have to image increasingly smaller structures on wafers. In order to take account of this trend, the exposure wavelength of lithography apparatuses is being shifted to ever shorter wavelengths. Future lithography systems will operate with wavelengths in the extreme ultraviolet (EUV) range (preferably but not exclusively in the range of 10 nm to 15 nm). The EUV wavelength range places huge demands on the precision of optical elements in the beam path of the future lithography systems. These are expected to be reflective optical elements, since the refractive index of the currently known materials in the EUV range is substantially equal to one.

EUV mask blanks comprise a substrate exhibiting little thermal expansion, such as quartz, for instance. A multilayer structure comprising approximately 40 to 60 double layers comprising silicon (Si) and molybdenum (Mo), for example, is applied to the substrate, said layers acting as a dielectric mirror. EUV photolithography masks or simply EUV masks are produced from mask blanks by use of an absorber structure being applied to the multilayer structure, which absorbs incident EUV photons.

On account of the extremely short wavelength, even tiny unevennesses of the multilayer structure are manifested in imaging aberrations of the wafer exposed by use of an EUV mask. Tiny unevennesses of the surface of the substrate typically propagate in the multilayer structure during the deposition of the multilayer structure onto the substrate. It is useful, therefore, to use substrates for producing EUV masks whose surface roughness is less than 2 nm (λ_{EUV}/4≦4 nm). At the present time it is very difficult to produce substrates which satisfy these requirements with regard to the flatness of their surfaces. Small substrate defects (≦20 nm) are currently considered to be inherent to a chemical mechanical polishing process (CMP).

As already mentioned, unevennesses of the substrate surface propagate in the multilayer structure during the deposition thereof. In this case, the defects of the substrate can propagate through the substrate substantially without being changed. Furthermore, it is possible for a substrate defect to propagate in the multilayer structure in a manner reduced in size or else increased in size. Alongside the defects caused by the substrate, additional defects can arise in the multilayer structure itself during the deposition of the multilayer structure. This can occur for example as a result of particles which deposit on the substrate surface or between the individual layers and/or on the surface of the multilayer structure. Furthermore, defects can arise in the multilayer structure as a result of an imperfect layer sequence. Overall, therefore, the number of defects present in the multilayer structure is typically more than the number present on the surface of the substrate.

Hereinafter, a substrate with applied multilayer structure and cover layer deposited thereon is referred to as a mask blank. In principle, however, other mask blanks are also conceivable in connection with the present invention.

The defects of the mask blank are usually measured after the deposition of the multilayer structure. The defects which are visible on a wafer (printable defects) upon exposure of the EUV mask that was produced from the mask blank are compensated for or repaired in the normal case. Compensating for a defect here means that said defect is substantially covered by an element of the absorber pattern, such that the defect is practically no longer visible upon exposure of a wafer using the EUV mask.

The publication “EUV mask defect mitigation through pattern placement” by J. Burns and M. Abbas, Photomask Technology 2010, edited by M. W. Montgomery, W. Maurer, Proc. of SPIE Vol. 7823, 782340-1-782340-5, describes the search for a mask blank which matches a predefined mask layout, and the alignment of the selected mask blank relative to the predefined mask layout.

The article “Using pattern shift to avoid blank defects during EUVL mask fabrication” by the authors Y. Negishi, Y. Fujita, K. Seki, T. Konishi, J. Rankin, S. Nash, E. Gallagher, A. Wagner, P. Thwaite and A. Elyat, Proc. SPIE 8701, Photomask and Next-Generation Lithography Mask Technology XX, 870112 (Jun. 28, 2013) is concerned with the question of how many defects of what size can be compensated for by shifting an absorber pattern.

The conference paper “EUVL ML Mask Blank Fiducial Mark Application for ML Defect Mitigation” by P. Yan, Photomask Technology 2009, edited by L. S. Zurbrick, M. Warren Montgomery, Proc. of SPIE, Vol. 7488, 748819-1-748819-8, describes the transfer of the coordinates of defects with respect to reference markings of the mask blank with respect to reference markings of the absorber layer.

The publication “EUVL Multilayer Mask Blank Defect Mitigation for Defect-free EUVL Mask Fabrication” by P. Yan, Y. Liu, M. Kamna, G. Zhang, R. Chem and F. Martinez, in Extreme Ultraviolet (EUV) Lithography III, edited by P. P. Naulleau. O. R. Wood II, Proc. of SPIE, Vol. 8322, 83220Z-1-83220Z-10 describes a compromise between the maximum number of defects which can be covered by an absorber pattern, their defect size, the variation with which the position of the defects can be determined, and the variation in the positioning of the absorber structure.

The patent specification U.S. Pat. No. 8,592,102 B1 describes the compensation of defects of a mask blank. To that end, that defect pattern of a mask blank which best matches an absorber pattern is selected from a set of mask blanks. The absorber pattern is aligned with the defect pattern, such that as many defects as possible are compensated for by the absorber pattern. The remaining defects are repaired.

The cited documents take into account in the compensation process defects with the same weight or order the defects according to the size thereof. As a result, firstly, a downstream repair process used to repair the non-compensated defects may become very complex and thus time-consuming. Secondly, the compensation process and the subsequent repair process may not lead to the best possible fault treatment result.

### SUMMARY

The present invention addresses the problem of specifying a method for producing a mask for the extreme ultraviolet wavelength range, a mask and a device for treating defects of a mask blank which at least in part avoid the abovementioned disadvantages of the prior art.

In accordance with a first aspect of the present invention, this problem is solved by a method for producing a mask for the extreme ultraviolet wavelength range proceeding from a mask blank having defects, the method comprising the following steps: (a) classifying the defects into at least one first group and one second group; (b) optimizing the arrangement of an absorber pattern on the mask blank in order to compensate for a maximum number of the defects of the first group by use of the arranged absorber pattern; and (c) applying the optimized absorber pattern to the mask blank.

The method according to the invention does not simply compensate for the maximum number of defects. Rather, it firstly classifies the defects present on a mask blank. Preferably, those defects of the mask blank which cannot be repaired are assigned to the group of the defects which are compensated for, i.e. to the first group. This ensures that all defects which are visible (i.e. printable) in a later exposure process can actually be treated or the number of remaining defects which cannot be compensated for remains below an acceptable value. The method according to the invention thus achieves the best possible defect treatment result during the production of a mask.

The method can furthermore comprise the step of at least partly repairing the defects of the second group by use of a repair method, wherein repairing the defects comprises modifying at least one element of the applied absorber pattern and/or modifying at least one part of a surface of the mask blank.

Modifying an element of the absorber pattern for the purpose of treating defects of the multilayer structure of a mask blank is also called “Compensational Repair” hereinafter.

Furthermore, in one exemplary embodiment the method comprises the step of further optimizing one or a plurality of elements of the absorber pattern before applying to the mask blank, in order at least partly to compensate for an effect of one or a plurality of defects of the second group. This further optimization makes it possible to further reduce the remaining outlay for repairing defects of the second group.

In one exemplary embodiment, a priority is assigned to each defect from the second group of defects or to each repairable defect. In order furthermore to utilize the optimization of the arrangement of an absorber pattern in the best possible way, the first group, i.e. preferably the group of the non-repairable defects, is additionally assigned, as much as possible, defects with high priority of the second group. The reassignment of the defects to the two groups makes it possible to optimize the entire defect treatment process with regard to the use of time and the use of resources.

According to a further aspect, step b. comprises choosing an absorber pattern from absorber patterns of a mask stack for fabricating an integrated circuit.

The defined method does not simply adapt a random absorber pattern to a defect pattern of the mask blank. Rather, it chooses from the absorber patterns of a mask stack that absorber pattern which best matches the defect pattern of the mask blank.

Another aspect of step b. can comprise the following step: choosing an orientation of the mask blank, displacing the mask blank and/or rotating the mask blank.

Another aspect furthermore comprises the step of: characterizing the defects of the mask blank for the purpose of determining whether a defect can be repaired by modifying an absorber pattern or whether a defect has to be compensated for by optimizing the arrangement of an absorber pattern.

By dividing the identified defects into two groups before carrying out the defect treatment processes, the flexibility of the process for optimizing the arrangement of an absorber pattern is increased. The optimization process has to take account of fewer defects and thus fewer boundary conditions.

In another aspect, characterizing the defects furthermore comprises determining an effective defect size, wherein the effective defect size comprises those parts of a defect after whose repair or compensation a remaining part of the defect is no longer visible on an exposed wafer and/or wherein the effective defect size is determined by errors in the characterization of a defect and/or on the basis of a non-telecentricity of a light source used for the exposure.

In other words, a plurality of, possibly opposing, viewpoints can be taken into account when determining the effective defect size: on the one hand that small “residues” of a defect no longer have noticeable effects during exposure, such that the effective defect size may be smaller than the entire defect, and on the other hand that the limits of the measurement accuracy and/or a non-telecentric exposure may have the effect that the effectively determined defect size is larger than the actual defect.

The utilization of an existing mask blank can be maximized by the concept of an effective defect size. Moreover, this concept allows the flexible introduction of a safety margin; by way of example, uncertainties in determining the defect position can be taken into account in said size.

In a further aspect, characterizing the defects furthermore comprises determining a propagation of the defects in a multilayer structure of the mask blank.

The propagation of a defect in the multilayer structure is important for the classification of a defect and thus also for the type of treatment of the defect.

In yet another aspect, step a. comprises classifying a defect into the at least one first group if the defect cannot be detected by surface-sensitive measurements, if the defect exceeds a predefined size and/or if different measurement methods when determining a position of the defect produce different results.

Defects which cannot be detected by surface-sensitive measurements can be localized for a repair—if at all—only with extremely high outlay. Defects whose effective defect area exceeds a specific size require very high defect treatment outlay. Moreover, in the case of very large defects there is the risk that they cannot be repaired in a single-stage process. In addition, for example if defects in a multilayer structure do not grow perpendicular to the layer sequence of the multilayer structure, different measurement methods yield different data about the position and the extent of said defects. A repair of such defects is possible, if at all, only with very large safety margins.

According to yet another aspect, step a. comprises classifying the defects of the mask blank not mentioned in the preceding aspect into the at least one second group.

All defects of a mask blank are thus coarsely classified.

An advantageous aspect furthermore comprises the step of: allocating a priority to the defects of the at least one second group. In yet another preferred aspect, the priority includes: an outlay for repairing a defect of the second group, and/or a risk when repairing a defect of the second group, and/or a complexity when repairing a defect of the second group and/or the effective defect size of a defect of the second group.

In accordance with a further aspect, a high priority is allocated to a defect of the second group if one or more of the following conditions are present: a time-consuming repair, deposition of at least one part of an absorber pattern element necessary, modification of the multilayer structure of the mask blank necessary, and a large effective defect size of the defect. According to yet another aspect, a low priority is allocated to a defect of the second group if one or more of the following conditions are present: a repair is not time-critical, removal of at least one part of the absorber pattern element necessary, an asymmetrical extent of the defect with a longitudinal direction running substantially parallel to a strip-shaped element of an absorber pattern, and a small effective defect size of the defect.

The expressions “large effective defect size” and “small effective defect size” relate to the average effective defect size of the printable or visible defects of a mask blank. An effective defect size is large (small), for example, if its size is double (half) that of the average effective defect size.

By a priority being allocated to the repairable defects, the classification of the defects of a mask blank is refined. Steps b. and c. of a defect treatment method defined above can thus be optimized.

Another aspect furthermore comprises the step of: allocating at least one defect with high priority to the at least one first group before performing step b. A further advantageous aspect furthermore comprises: repeating the process of allocating at least one defect with high priority to the at least one first group as long as all defects of the first group of defects can be compensated for by optimizing an absorber pattern.

The first group of defects is filled with defects of high priority of the second group until an optimized arrangement of an absorber pattern compensates for all defects of the first group. This procedure maximizes the number of defects which is compensated for by the optimization of the arrangement of an absorber pattern. The classification of the repairable defects in the second group thus has the advantage that the subsequent defect treatment process can be optimized on the basis of the priority of the repairable defects.

Yet another advantageous aspect furthermore comprises the step of: determining whether all defects of the mask blank which are visible on a wafer can be compensated for by the optimization of an absorber pattern.

If a mask blank has a small number of defects, it may be possible to compensate for all defects by an optimized arrangement of an absorber pattern. Carrying out step c. of the method defined above can be omitted in this case.

In accordance with a further aspect, the method defined above furthermore comprises the step of: dividing the process of at least partly repairing the second group into two substeps, wherein the first substep is carried out before the process of compensating for the defects of the first group.

By virtue of the defects of a mask blank being classified before their treatment, a greater flexibility in the repair of the defects is furthermore achieved. In this regard, by way of example, a modification of the surface of a multilayer structure can already be carried out on the mask blank instead of not being carried out until on the EUV mask. In a compensational repair for repairing the defects of the second group, one or a plurality of elements of an applied absorber pattern is/are changed.

However, it is also possible for the defects of the second group already to be taken into account when generating an absorber pattern, rather than the absorber pattern just generated being modified in a second repair step involving high outlay. An absorber pattern additionally optimized in this way compensates for the defects of the first group and furthermore at least partly compensates for an effect of at least one of the defects of the second group. In this embodiment, optimizing an absorber pattern comprises not only optimizing the arrangement of the pattern on the mask blank, but also optimizing the elements of the absorber pattern with regard to defects of the second group.

In accordance with a further aspect, the present invention relates to a mask producible by one of the methods explained above.

In accordance with a further aspect, a device for treating defects of a mask blank for the extreme ultraviolet wavelength range comprises: (a) means for classifying the defects into at least one first group and one second group; (b) means for optimizing the arrangement of an absorber pattern on the mask blank in order to compensate for a maximum number of the defects of the first group by use of the arranged absorber pattern; and (c) means for applying the optimized absorber pattern to the mask blank.

In a further preferred aspect, the means for classifying the defects and the means for optimizing the arrangement of an absorber pattern comprise at least one computing unit.

The device can furthermore comprise means for at least partly repairing the defects of the second group.

In accordance with a further advantageous aspect, the means for at least partly repairing the defects of the second group comprise at least one scanning particle microscope and at least one gas feed for locally providing a precursor gas in a vacuum chamber.

According to yet another aspect, the device furthermore comprises means for characterizing the defects of a mask blank, wherein the means for characterizing comprise a scanning particle microscope, an X-ray beam apparatus and/or a scanning probe microscope.

Finally, in one advantageous aspect, a computer program comprises instructions for carrying out all the steps of a method according to any of the aspects specified above. In particular, the computer program can be executed in the device defined above.

### DESCRIPTION OF DRAWINGS

The following detailed description describes currently preferred exemplary embodiments of the invention, with reference being made to the drawings, in which:

FIG. 1 schematically shows a cross section of an excerpt from a photomask for the extreme ultraviolet (EUV) wavelength range;

FIG. 2 schematically represents a cross section through an excerpt from a mask blank in which the substrate has a local depression;

FIG. 3 schematically elucidates the general concept of the effective defect size at a local bulge of a mask blank;

FIG. 4 illustrates FIG. 2 with a reference marking for determining the position of the centroid of the defect;

FIG. 5 reproduces a buried defect that changes its form during the propagation in the multilayer structure;

FIG. 6 schematically illustrates measurement data of a buried defect that does not propagate perpendicular to the layer sequence of the multilayer structure;

FIG. 7 schematically indicates the effective defect size of the defect from FIG. 6 which is actually to be compensated for or corrected and which results when taking account of the non-telecentricity of the incident EUV radiation and the statistical errors when determining the position and the effective defect size;

FIGS. 8A and 8B schematically show the effect of the absent telecentricity of the incident EUV radiation in sub-Figure 8A and illustrates the effect on an element of the absorber pattern in sub-Figure 8B;

FIGS. 9A-9C schematically illustrate the general concept of the compensation of defects of mask blanks in sub-figures 9A to 9C;

FIG. 10 indicates the implementation of the general concept—illustrated in FIGS. 9A to 9C—for compensating for defects of mask blanks according to the prior art; and

FIGS. 11A and 11B present one embodiment of the method defined in the preceding section.

### DETAILED DESCRIPTION

Currently preferred embodiments of a method according to the invention are explained in greater detail below on the basis of the application to mask blanks for producing photolithographic masks for the extreme ultraviolet (EUV) wavelength range. However, the method according to the invention for treating defects of a mask blank is not restricted to the examples discussed below. Rather, this method can generally be used for treating defects which can be classified into different classes, wherein the different classes of the defects are treated by use of different repair methods.

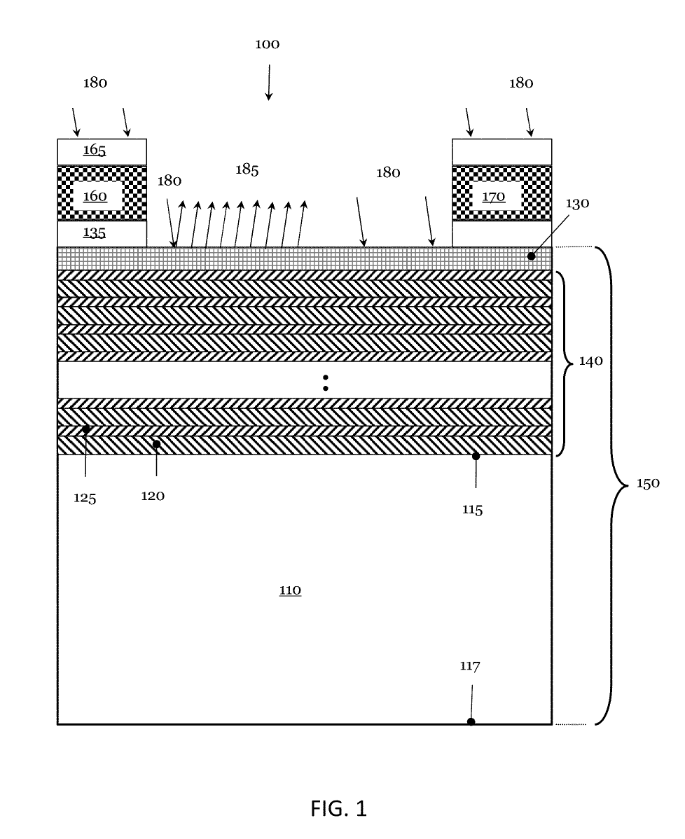

FIG. 1 shows a schematic section through an excerpt from an EUV mask 100 for an exposure wavelength in the region of 13.5 nm. The EUV mask 100 comprises a substrate 110 composed of a material having a low coefficient of thermal expansion, such as quartz, for example. Other dielectrics, glass materials or semiconducting materials can likewise be used as substrates for EUV masks, such as ZERODUR®, ULE® or CLEARCERAM®, for instance. The rear side 117 of the substrate 110 of the EUV mask 100 serves for holding the substrate 110 during the production of the EUV mask 100 and in the operation thereof.

A multilayer film or a multilayer structure 140 comprising 20 to 80 pairs of alternating molybdenum (Mo) 120 and silicon (Si) layers 125, which are also designated hereinafter as MoSi layers, is deposited onto the front side 115 of the substrate 110. The thickness of the Mo layers 120 is 4.15 nm and the Si layers 125 have a thickness of 2.80 nm. In order to protect the multilayer structure 140, a capping layer 130 composed of silicon dioxide, for example, typically having a thickness of preferably 7 nm, is applied on the topmost silicon layer 125. Other materials such as ruthenium (Ru), for example, can likewise be used for forming a capping layer 130. Instead of molybdenum, in the MoSi layers it is possible to use layers composed of other elements having a high mass number, such as cobalt (Co), nickel (Ni), tungsten (W), rhenium (Re) and iridium (Ir), for instance. The deposition of the multilayer structure 240 can be effected by ion beam deposition (IBD), for example.

The substrate 110, the multilayer structure 140 and the capping layer 130 are referred to hereinafter as mask blank 150. However, it is also possible to refer to the structure as a mask blank comprising all the layers of an EUV mask, but without structuring of the whole-area absorber layer.

In order to produce an EUV mask 100 from the mask blank 150, a buffer layer 135 is deposited on the capping layer 130. Possible buffer layer materials are quartz (SiO₂), silicon oxygen nitride (SiON), Ru, chromium (Cr) and/or chromium nitride (CrN). An absorption layer 160 is deposited on the buffer layer 135. Materials suitable for the absorption layer 160 are, inter alia, Cr, titanium nitride (TiN) and/or tantalum nitride (TaN). An antireflection layer 165, for example composed of tantalum oxynitride (TaON), can be applied on the absorption layer 160.

The absorption layer 160 is structured for example with the aid of an electron beam or a laser beam, such that an absorber pattern 170 is generated from the whole-area absorption layer 160. The buffer layer 135 serves to protect the multilayer structure 140 during the structuring of the absorption layer 160.

The EUV photons 180 impinge on the EUV mask 100. In the regions of the absorber pattern 170, said photons are absorbed and, in the regions that are free of elements of the absorber pattern 170, the EUV photons 180 are reflected from the multilayer structure 140.

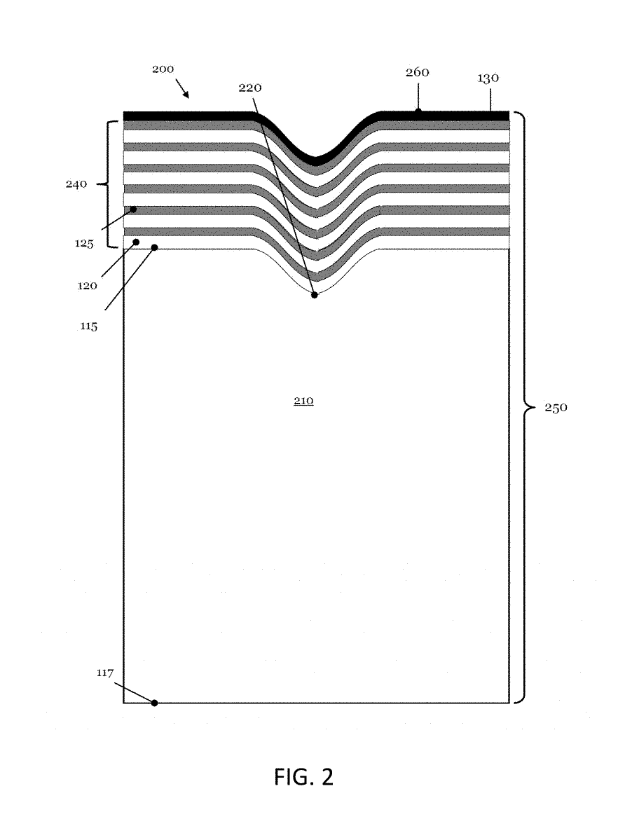

FIG. 1 illustrates an ideal EUV mask 100. The diagram 200 in FIG. 2 elucidates a mask blank 250 whose substrate 210 has a local defect 220 in the form of a local depression (referred to as: pit). The local depression may have arisen for example during the polishing of the front side 115 of the substrate 210. In the example elucidated in FIG. 2, the defect 220 propagates substantially in unchanged form through the multilayer structure 240.

Here as well as elsewhere in the present description, the expression “substantially” means an indication or a numerical indication of a variable within the measurement errors customary in the prior art.

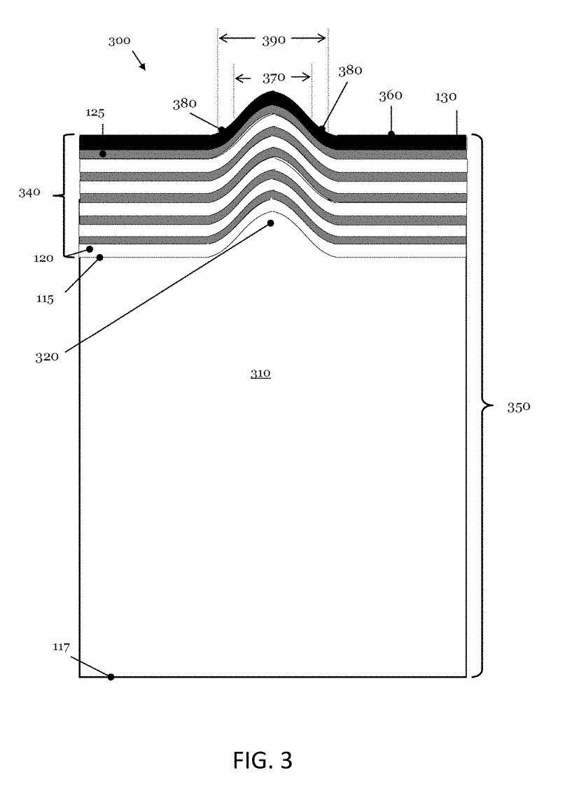

FIG. 2 shows one example of a defect 220 of a mask blank 250. As already mentioned in the introductory part, various further types of defect may be present in a mask blank 250. Alongside depressions 220 of the substrate 210, local bulges (referred to as: bumps) may occur on the surface 115 of the substrate 210 (cf. subsequent FIG. 3). Furthermore, tiny scratches may arise during the polishing of the surface 115 of the substrate 210 (not illustrated in FIG. 2). As already discussed in the introductory part, during the deposition of the multilayer structure 240, particles on the surface 115 of the substrate 210 may be overgrown or particles may be incorporated into the multilayer structure 240 (likewise not shown in FIG. 2).

The defects of the mask blank 250 may have their starting point in the substrate 210, on the front side or the surface 115 of the substrate 210, in the multilayer structure 240 and/or on the surface 260 of the mask blank 250 (not shown in FIG. 2). Defects 220 that are existent on the front side 115 of the substrate 210 may—in contrast to the illustration shown in FIG. 2—change both their lateral dimensions and their height during the propagation in the multilayer structure 240. This may occur in both directions, i.e. a defect may grow or shrink in the multilayer structure 240 and/or may change its form. Defects of a mask blank 250 which do not originate exclusively on the surface 260 of the capping layer 130 are also referred to hereinafter as buried defects.

Ideally, the lateral dimensions and the height of a defect 220 should be determined with a resolution of less than 1 nm. Furthermore, the topography of a defect 220 should be determined independently of one another by different measurement methods. For measuring the contour of the defect 220, the position thereof on the surface 260 and in particular the propagation thereof in the multilayer structure 240, X-rays may be used, for example.

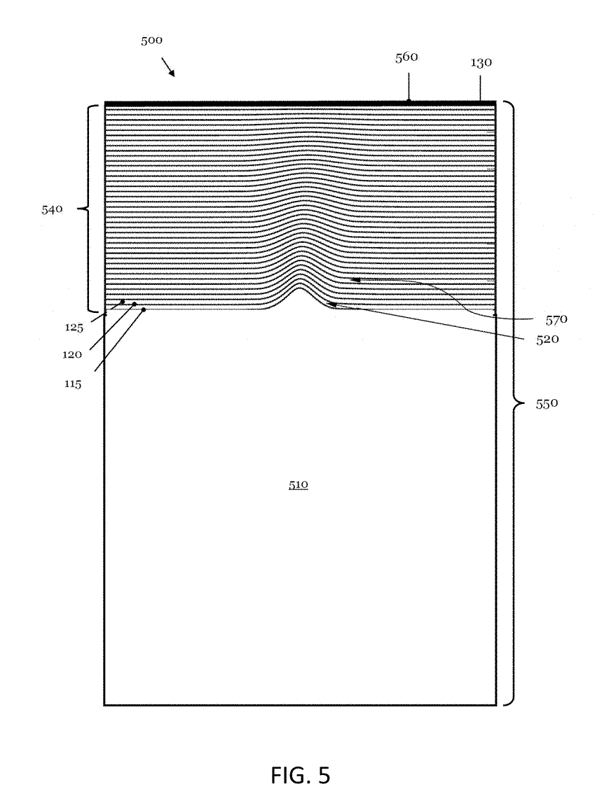

The detection limit of surface-sensitive methods relates to the detectability or the detection rate of the defect position (i.e. its centroid) by use of these methods. Scanning probe microscopes, scanning particle microscopes and optical imaging are examples of surface-sensitive methods. A defect 220 which is intended to be detected by such techniques must have a specific surface topography or a material contrast. The resolvable surface topography or the required material contrast depends on the performance of the respective measuring instrument, such as, for instance, the height resolution thereof, the sensitivity thereof and/or the signal-to-noise ratio thereof. As will be explained below on the basis of the example in FIG. 5, there are buried phase defects which are planar on the surface of the mask blank and therefore cannot be detected by surface-sensitive methods.

The diagram 300 in FIG. 3 elucidates the concept of the effective defect size of a defect. The example in FIG. 3 represents a section through the local defect 320 having the form of a bulge of the front side 115 of the substrate 230. In a manner similar to that in FIG. 2, the local defect 320 propagates substantially unchanged through the multilayer structure 340. The region 370 of the surface 360 represents the effective defect size of the defect 320. Said size relates to the lateral dimensions of the defect 320 which are used both for compensation and for repair of the defect 320. As symbolized in FIG. 3, generally the effective defect size 370 is smaller than the real lateral dimensions of the defect 320. For a defect 320 having a Gaussian profile, the effective defect size could correspond to once or twice the full width half maximum (FWHM) of the defect 320.

If the region 370 of the effective defect size is repaired, then the remaining residues 380 of the defect 320 no longer lead to a fault that is visible on a wafer during the exposure of an EUV mask produced from the mask blank 350. The concept of the effective defect size, by virtue of minimizing the size of the individual defects 220, 320, enables an efficient utilization of mask blanks 250, 350 during the production of EUV masks. Moreover, this concept allows a resource-efficient repair of the defects 220, 320.

The region 390 indicates a safety margin that can be taken into account when determining the position of the defect 320 and the contour thereof. With the additional safety margin, the effective defect size 370 of the defect 320 can be smaller, equal to or larger than the lateral dimensions of the real defect 320. In addition, for determining the effective defect size, preferably the viewpoints explained further below are taken into account which concern, inter alia, unavoidable errors when determining the position of the real defect, and also the non-telecentricity of a light source used for the exposure of the mask.

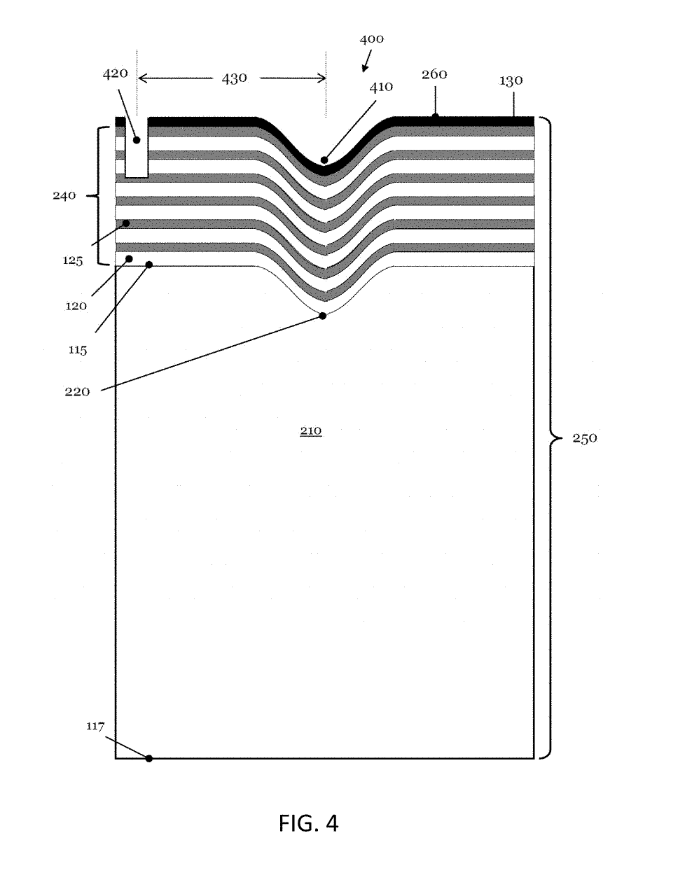

The diagram 400 in FIG. 4 elucidates the localization of the centroid 410 of the defect 220 from FIG. 2 with respect to a coordinate system of the mask blank 250. A coordinate system is produced on the mask blank 250 for example by etching a regular arrangement of reference markings 420 into the multilayer structure 240 of said mask blank. The diagram 400 in FIG. 4 represents one reference marking 420. The positional accuracy of the distance 430 between the centroid 410 of the defect 220 and the reference marking 420 should be better than 30 nm (with a deviation of 3σ), preferably better than 5 nm with preference (with a deviation of 3σ), in order that a compensation of the defect by optimizing the arrangement of the absorber pattern 170 becomes possible. Currently available measuring instruments have a positional accuracy in the region of 100 nm (with a deviation of 3σ).

In a manner similar to the determination of the topography of the defects 220, 320, the determination of the distance 430 of the centroid 410 with respect to one or more reference markings 420 should be determined independently with the aid of a plurality of measurement methods. By way of example, actinic imaging methods such as, for instance, an AIMS™ (Aerial Image Messaging System) for the EUV wavelength range and/or an apparatus for ABI (Actinic Blank Inspection), i.e. a scanning dark-field EUV microscope for detecting and localizing buried EUV blank defects, are appropriate for this purpose. Furthermore, surface-sensitive methods can be used for this purpose, for example a scanning probe microscope, a scanning particle microscope and/or optical imagings outside the actinic wavelength. Moreover, methods which measure the defect 220, 320 at its physical position within the mask blank 250, 350, such as X-rays, for instance, can also be used for this purpose.

It is complicated to detect defects of the multilayer structure 240 which do not stand out on the surface 260 but nevertheless lead to visible faults during the exposure of the EUV mask. In particular, it is difficult to define the exact position of such defects. The diagram 500 in FIG. 5 shows a section through an excerpt from a mask blank 550 in which the surface 115 of the substrate 510 has a local bulge 520. The local defect 520 propagates in the multilayer structure 540. The propagation 570 leads to a gradual attenuation of the height of the defect 520 accompanied by an increase in the lateral dimensions thereof. The final layers 120, 125 of the multilayer structure 540 are substantially planar. On the capping layer 130, no elevation can be determined in the region of the defect 520.

In current repair methods, particularly in compensational repair, it is necessary, however, to find the position at which the repair is to be carried out. The defect 520 is thus unsuitable for a repair and must therefore be compensated for by covering with an element of the absorber pattern 170.

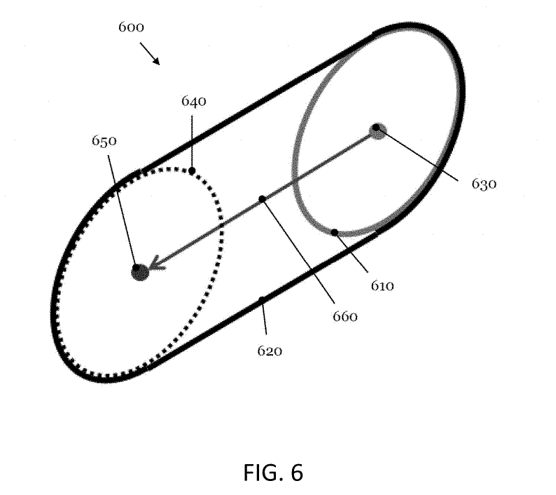

Moreover, there are defects which do not propagate perpendicular to the layers 120, 125 of the multilayer structure 240, but rather at an angle different than 90°. For these defects it is likewise difficult to determine their position and their topography and thus to indicate their effect during the exposure of a wafer. If the defect positions of an individual defect 220, 320 that are obtained by use of different methods clearly deviate from one another, this is a sign that a buried defect has growth facing away from the perpendicular in the multilayer structure 240, 440. The diagram 600 in FIG. 6 elucidates this relationship on the basis of the defect 620. The contour 610 reproduces the defect such as was determined for example with the aid of X-ray radiation. The point 630 indicates the centroid of the defect in the vicinity of the surface 115 of the substrate 210, 410. Instead of X-ray radiation, the defect 620 can be examined for example by use of optical radiation through the substrate 210, 410 at the surface 115.

The contour 640 represents the topology of the defect 620 at the surface 260, 460 of the capping layer 130 on the multilayer structure 240, 440 such as is measured by use of a scanning probe microscope, for example an atomic force microscope (AFM). The size of the defect 620 substantially does not change as a result of the propagation of the defect 620 in the multilayer structure 240, 440. The point 650 in turn indicates the centroid of the defect 620 on the surface 260, 460 of the capping layer 130. However, the centroid of the defect 620 shifts along the arrow 660 during growth in the multilayer structure 240, 440, which indicates that the defect 620 does not grow in a vertical direction within the multilayer structure 240, 440.

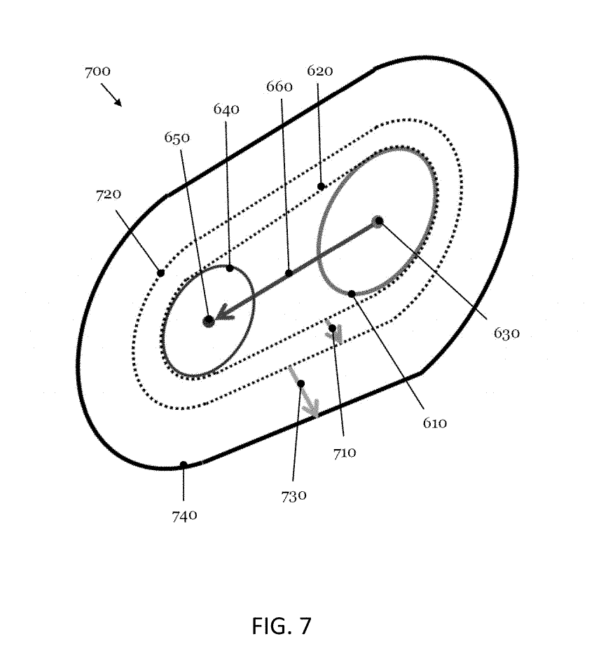

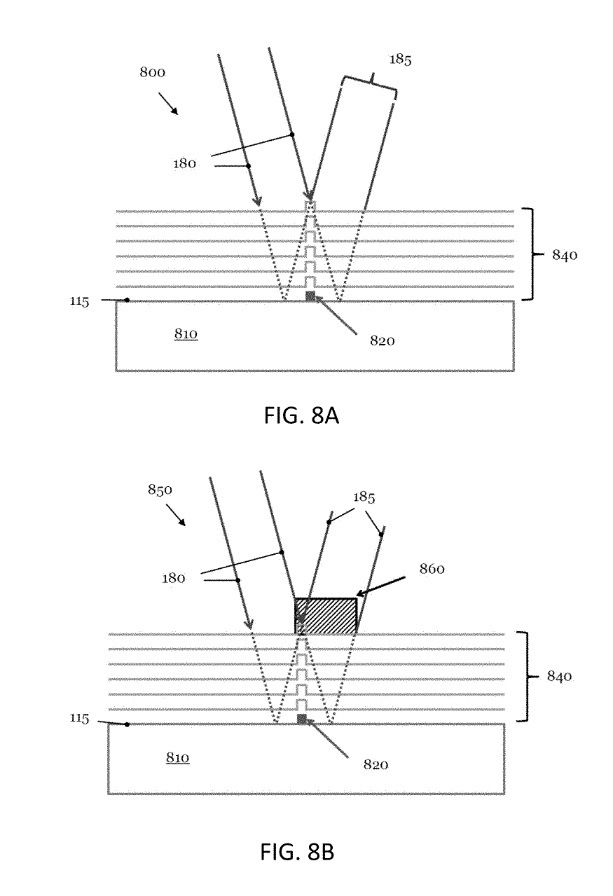

The accuracy of the measurement of the defect position of the defect 620 with respect to the reference marking(s) 420 is illustrated in FIG. 7. The achievable accuracy is composed of a plurality of contributions: firstly, the accuracy of the defect localization, on account of the non-telecentricity of the incident EUV photons 180, depends on the reflectivity of the multilayer structure 240, 440. FIG. 8A elucidates this relationship. Owing to the limited reflectivity of the individual MoSi layers of the multilayer structure 840, individual EUV photons 180 can penetrate as far as the surface 115 of the substrate 810 and are reflected from said surface. FIG. 8B shows that, as a result of this effect, an area 850 which is significantly larger than lateral dimensions of the defect 820 has to be covered by an element of the absorber pattern 170.

In FIG. 7, the arrow 710 symbolizes the apparent enlargement 720 of the defect size 620 that is caused as a result.

Secondly, the achievable accuracy is influenced by the precision with which it is possible to determine the defect size 640 and the centroid 650 of the defect 620 on the surface 260, 460, and likewise its propagation 660 in the multilayer structure 240, 440. Furthermore, this is influenced by the accuracy with which the tool for repairing the defect, for example a scanning particle microscope or a scanning electron microscope, can be positioned. The last-mentioned factor depends in turn on the accuracy of determining the distance 430 with respect to one or more reference markings 420. These errors are of statistical nature. They must be taken into account when determining the defect size to be compensated for or to be repaired. The enlargement of the area to be repaired of the defect 620, which enlargement is brought about on account of these statistical uncertainties, is symbolized by the arrow 730 and the contour 740 in FIG. 7.

Overall—alongside the above-explained viewpoint of the visibility of the defect during exposure—the effective defect size 740 thus arises, which is preferably used in the method explained.

For examining the defects 220, 320, 520, 620 of the mask blank 250, 350, 550, further powerful tools are available besides those already mentioned. In this regard, the patent application DE 10 2011 079 382.8 in the name of the present applicant describes methods which can be used to examine defects of an EUV mask. A scanning probe microscope, a scanning particle microscope and an ultraviolet radiation source are used for analyzing the defects. The contour of the defect 220 and the position thereof can be determined with the aid of these surface-sensitive methods.

Furthermore, the application DE 2014 211 362.8 discloses a device which makes it possible to analyze the front side 115 of a substrate 210 of a mask blank 250 in detail and thus to determine the defect position on the front side 115 of the substrate 210 of a mask blank 250.

In addition, the PCT application WO 2011/161 243 in the name of the present applicant discloses determining a model of a defect 220, 320, 520, 620 of the multilayer structure 240, 340, 540 on the basis of generating a focus stack, examining the surface 260, 360, 560 of the multilayer structure 240, 340, 540 and various defect models.

After the examination of the defect 220, 320, 520, 620, a defect position, i.e. the centroid of the defect, and a defect topology are calculated from the measurement data of the analysis tools. An effective defect size is determined from the defect topology or the defect contour. Overall, a defect map listing the position and the effective defect size 370, 740 of the individual printable defects 220, 320, 520, 620 is thus determined from a mask blank 250, 350, 550.

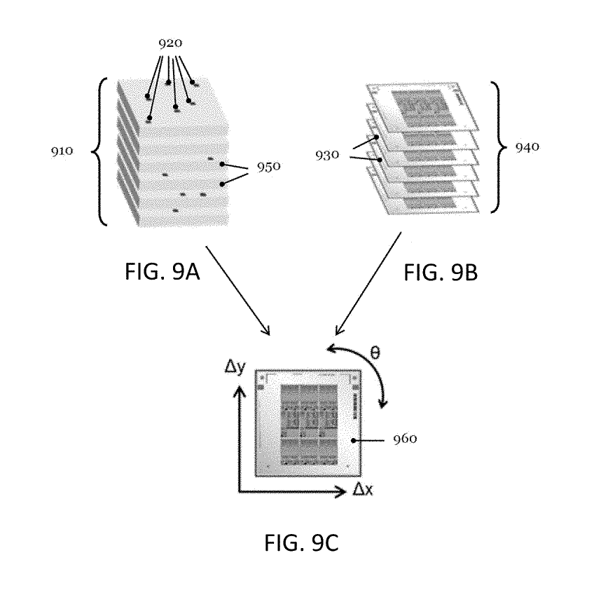

FIG. 9A shows a number or a stack 910 of mask blanks 950 which in each case has one or a plurality of defects 920. In FIG. 9A, the defects 920 are symbolized by black dots. The situation in which a mask blank 950 has a plurality of types of defects 920 is often encountered. The number of critical, i.e. visible or printable, defects 920 of a mask blank 950 is currently typically in the range of from 20 to several hundred. The critical defect size is dependent on the technology node under consideration. By way of example, for the 16 nm technology node, defects 920 having a spherical-volume-equivalent diameter of approximately 12 nm are already critical.

Typically, the plurality of defects 920 originate from local depressions 220 of the substrate 210 of the mask blanks 950 (cf. FIG. 2). As already explained above, the defects 920 of a mask blank 950 can be examined for example by an examination by use of radiation in the range of the actinic wavelength.

FIG. 9B reproduces a library 940 of mask layouts 930. The library 940 may contain only one mask stack with the mask layouts 930 of a single integrated circuit (IC) or of a single component. It is preferred, however, for the library 940 to comprise mask stacks of the layouts 930 of different ICs or components. Furthermore, it is advantageous if the library 940 includes mask layouts 930 of different technology nodes. For a mask blank 950 of the stack 910, the mask layout 930 which best matches the defects 920 of the mask blank 950 is then selected from the library 940. The correspondence can be made all the better, the fewer the number of boundary conditions imposed for the selection of the mask layout 930 from the library 940.

For the selected mask layout 960, the absorber pattern 170 thereof is then adapted to the mask blank 950 in an optimization process. This process is illustrated schematically in FIG. 9C. The following are currently available as optimization parameters: the orientation of the mask layout 960 relative to the mask blank 950, i.e. the four orientations 0°, 90°, 180° and 270°.

Furthermore, a shift of the mask layout 960 and thus of the absorber pattern 170 relative to the mask frame in the x- and y-directions. Shifting the layout 960 or the absorber pattern 170 can be compensated for by a wafer stepper by use of an oppositely directed shift of the mask frame. The shift of the absorber pattern 170 is currently limited to ≦±200 μm. Present-day wafer steppers can compensate for a mask offset up to this magnitude.

Finally, the oriented mask pattern 960 can be rotated by up to an angle of ±1°. Rotations of photomasks in this angular range can likewise be compensated for by modern likewise wafer steppers.

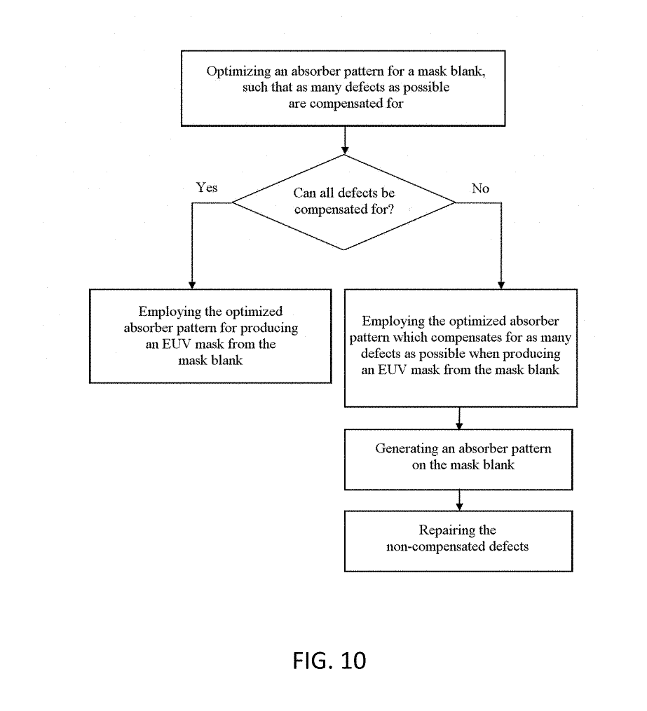

FIG. 10 elucidates how the optimization process described in FIGS. 9A-9C is performed in the prior art. As explained above during the discussion of FIGS. 9A-9C, the general concept of the compensation of defects 920 of a mask blank 950 is to adapt the latter to a mask layout 960 in order to cover as many defects 920 of the mask blank 950 as possible with elements of the absorber pattern 170. The orientation, a shift in the x- and y-directions, can—as likewise described above—additionally be used to improve the probability of covering the defects 920. As illustrated in FIG. 10, current defect compensation processes maximize the number of compensated defects 920 of a mask blank 950. At the end of the optimization process it is ascertained whether all of the defects 920 can be compensated for. If this is the case, the optimized mask layout 960 is used for producing an EUV mask from the mask blank 950. If this is not the case, the optimized mask layout is nevertheless used for producing an EUV mask and the remaining or non-compensated defects must be repaired.

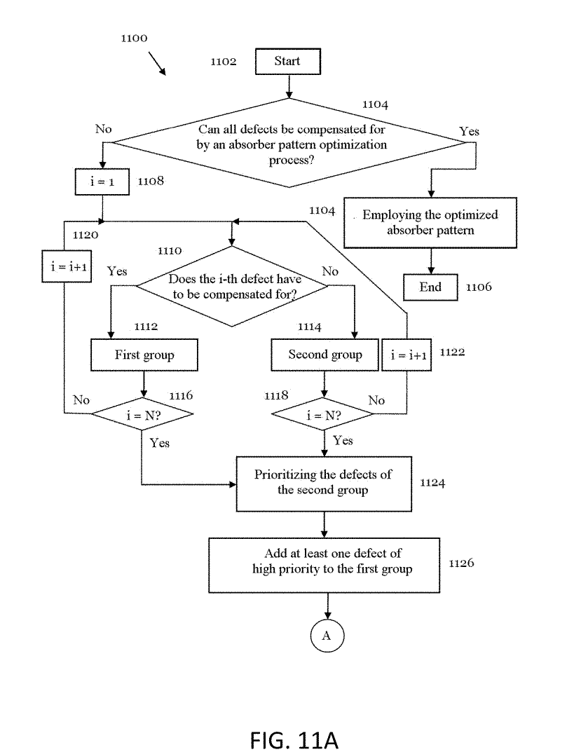

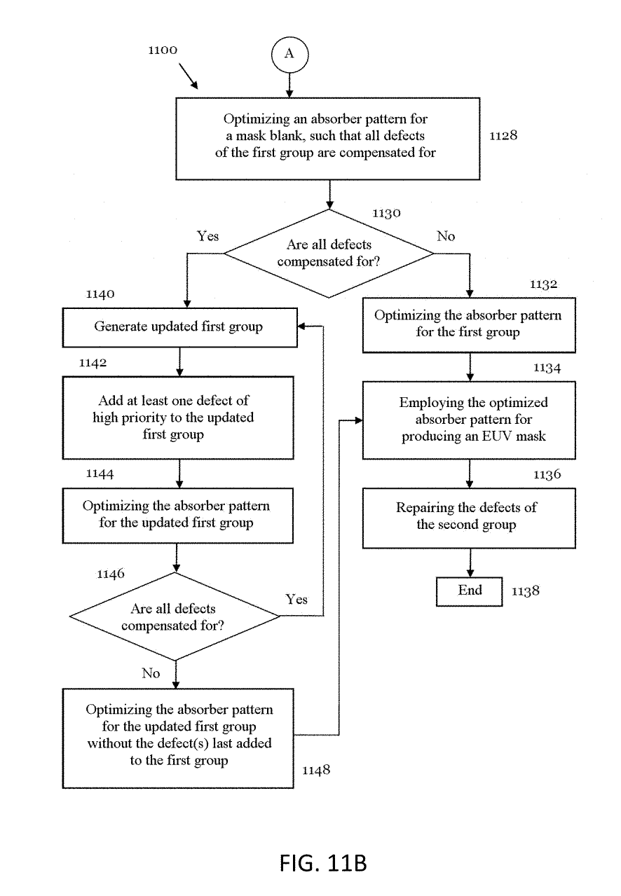

Finally, FIGS. 11A and 11B show a flow diagram 1100 of one exemplary embodiment of the method defined in this application. The method starts at step 1102. Decision block 1104 involves ascertaining whether all of the defects 920 of a mask blank 950 can be compensated for by the optimization of the absorber pattern 170 of the mask layout 960. Compensating in this application here means covering the defects by elements of the absorber pattern 170, such that the defects 920, during the exposure of an EUV mask that is produced from the mask blank 950, has no printable or visible defects on a wafer.

If all of the defects 920 can be compensated for, with the aid of the absorber pattern 170 arranged in an optimized manner, in step 1104, an EUV mask is produced from the mask blank 950 and the method ends with step 1106.

If not all of the defects 920 of the mask blank 950 can be compensated for, in step 1108 a counter is set to its initial value. Decision block 1110 then involves deciding whether the defect 920 currently under consideration can be repaired or whether it must be compensated for. If the defect of the mask blank 950 currently under consideration must be compensated for, said defect is classified into the first group in step 1112. Defects 520, 620 which are to be assigned to the first group are described in FIGS. 5 and 6. Furthermore, defects whose effective defect size is very large in comparison with the average effective defect size of the mask blank 950 should likewise be classified into the first group. The repair of very large defects is very complicated. In particular, it may be necessary to carry out the repair in a plurality of steps. There is therefore the risk that other regions of the surface of an EUV mask may be impaired during the repair of very large defects 920.

Decision step 1116 then involves determining whether the defect 920 currently under consideration is the last defect 920 of the mask blank 950. If this question is answered in the negative, the method advances to step 1120 and the index of the counter for the defects is increased by one unit. The method then continues with decision block 1110 and the (i+1)-th defect 920 is analyzed. If the defect 920 under consideration is the last defect 920 of the mask blank 950 (i=N), the method continues with step 1124.

By contrast, if the defect 920 can be repaired, it is classified into the second group in step 1114. Decision block 1118 in turn involves deciding whether the i-th defect is the last defect 920 of the mask blank 950. If this question should be answered in the negative, in step 1122 the index of the counter of the defects 920 is increased by one unit. Afterward, the method continues with decision block 1110. By contrast, if the i-th defect 920 under consideration is the last defect of the mask blank 950, step 1124 is performed next.

The defects of the second group are prioritized in step 1124. The priority allocated to the defects of the second group combines a plurality of features of the defect 920 itself and/or aspects in the repair thereof. The priority can assume two values, for instance a high priority or a low priority. However, the priority levels can also be chosen with finer granularity and have an arbitrary scale, such as numerical values from 1 to 10, for example.

One example of a defect-internal feature is the effective defect size 370, 740. The larger the effective defect size 370, 740, the higher its priority. Aspects of the defect repair which influence the definition of the priority of a defect are, for example, the outlay required for repairing the defect 920. Examples of further aspects which play a part in the assessment of the priority of a defect 920 are the complexity and the risk of the repair of the defect.

Instead of classifying the defects 920 of a mask blank 950 into two groups and prioritizing the defects in the second group, it is also possible to divide the defects into more than two groups. In this case, the non-repairable defects are still classified into the first group. The repairable defects are allocated to the further groups in accordance with their priority.

Furthermore, it is also possible to reverse the process of allocating defects to the second group to the first group. This means that, for example, all defects with high priority are redistributed from the second to the first group. If it is not possible to compensate for all of the defects of the greatly enlarged first group, the defects newly added to the first group are allocated again progressively to the second group.

After prioritizing the defects of the second group, the method continues with step 1126. In this step, at least one defect of the second group which has a high priority or the highest priority is assigned to the first group. The method described here is flexible with regard to the number of defects which are added to the first group in step 1126. In this regard, one, two, five or 10 defects of high priority from the second group can be allocated to the first group in one step, for example. It is furthermore conceivable for the number of defects shifted from the second to the first group to be made dependent on the defect pattern of the mask blank 950.

The next step 1128 involves—as explained in the discussion of FIGS. 9A-9C—selecting a mask layout 960 which matches the first group of defects 920 of the mask blank 950 in the best possible way. Furthermore—as likewise described in FIGS. 9A-9C—the arrangement of the selected absorber pattern 170 on the mask blank 950 is optimized.

Decision block 1130 then involves deciding whether the absorber pattern 170 optimized with regard to the arrangement can compensate for all of the defects of the first group and the defects 920 added from the second group. If this is not the case, the defects added from the second group are referred back to the second group again and in step 1132 the method performs an optimization process with the first group of defects in accordance with FIGS. 9A-9C. In step 1134, with the aid of the absorber pattern 170 arranged in an optimized manner, an EUV mask is then produced from the mask blank 950.

The defects 920 of the second group are repaired in step 1136. For repairing the defects 920 of the second group, first of all it is possible to employ the method of compensational repair as already mentioned. Furthermore, in the patent application U.S. 61/324 467 the applicant has disclosed a method which makes it possible to alter the surface 115 of a substrate 210, 310, 510 in a targeted manner and thereby to repair the defects 920 of the second group. The application WO 2011/161 243 in the name of the present applicant, as already mentioned above, describes the repair of defects 920 on the surface 115 of a mask substrate 210, 310, 510 with the aid of an ion beam.

If it is then ascertained in decision block 1130 that the optimization process in step 1128 can compensate for all defects of the updated first group including the defects newly added in the last step 1142, an updated first group is generated in step 1140. The updated first group comprises the first group plus the defects that were added to the first group in step 1126. In step 1144, one or a plurality of defects of the second group with high priority are allocated to the updated first group. For this new group of defects, the optimization process explained with reference to FIGS. 9A-9C is performed in step 1144.

In decision block 1146 it is ascertained whether all of the defects 920 can still be compensated for. If this is the case, the method continues to block 1140 and generates a newly updated first group containing more defects 920 than the updated first group generated originally. The method iterates the loop of steps 1140, 1142, 1144 and of decision block 1146 until the optimization process in step 1144 can no longer compensate for all of the defects. In step 1148, the method determines the updated first group, i.e. the updated first group without the defects from the second group that were added in the last step 1142. The defects of the updated first group thus determined can be compensated for by the optimization process 1144.

The method then advances to step 1134 and generates an EUV mask from the mask blank 950 with the aid of the absorber pattern 170 arranged in an optimized manner. As described above, the remaining defects of the second group are repaired in block 1136. Finally, the method ends in step 1138.

Although not illustrated in the flow diagram in FIG. 11, it is additionally possible, before employing the optimized absorber pattern in step 1134, to carry out a further optimization which—whilst maintaining the compensation of the defects of the first group—modifies individual elements of the absorber pattern in order at least partly to compensate for an effect of one or a plurality of defects of the second group. This can be achieved for example by altering the form and size of individual elements of the absorber pattern. The outlay when repairing the remaining defects of the second group in step 1136 is thereby reduced further.

By classifying the defects of a mask blank into at least two groups, the method presented ensures that all relevant printable defects of a mask blank can be eliminated. Furthermore, the classification of the defects into two or more groups enables a resource-efficient defect treatment process.

What is claimed is:

1. A method for producing a mask for the extreme ultraviolet wavelength range proceeding from a mask blank having defects, wherein the method comprises the following steps:
a. classifying the defects into at least one first group and one second group;
b. allocating a priority to the defects of the at least one second group;
c. optimizing the arrangement of an absorber pattern on the mask blank in order to compensate for a maximum number of the defects of the first group by use of the arranged absorber pattern; and
d. applying the optimized absorber pattern to the mask blank.

2. The method as claimed in claim 1, furthermore comprising the step of:
at least partly repairing the defects of the second group by use of a repair method.

3. The method as claimed in claim 2, wherein repairing the defects comprises
modifying at least one element of the applied absorber pattern and/or modifying at least one part of a surface of the mask blank.

4. The method as claimed in claim 1, furthermore comprising the step of:
further optimizing one or a plurality of elements of the absorber pattern before applying to the mask blank, in order at least partly to compensate for an effect of one or a plurality of defects of the second group.

5. The method as claimed in claim 1, wherein step c. comprises: choosing an absorber pattern from absorber patterns of a mask stack by means of the method for producing an integrated circuit.

6. The method as claimed in claim 1, wherein step c. comprises: choosing an orientation of the mask blank, displacing the mask blank and/or rotating the mask blank.

7. The method as claimed in claim 1, furthermore comprising the step of:
characterizing the defects of the mask blank for the purpose of determining whether a defect can be repaired by modifying an absorber pattern or whether a defect has to be compensated for by optimizing the arrangement of the absorber pattern.

8. The method as claimed in claim 7, wherein characterizing the defects furthermore comprises: determining an effective defect size, wherein the effective defect size comprises those parts of a defect after whose repair or compensation a remaining part of the defect is no longer visible on an exposed wafer and/or wherein the effective defect size is determined by errors in the characterization of a defect and/or on the basis of a non-telecentricity of a light source used for the exposure.

9. The method as claimed in claim 7, wherein characterizing the defects furthermore comprises: determining a propagation of the defects in a multilayer structure of the mask blank.

10. The method as claimed in claim 1, wherein step a. comprises: classifying a defect into the at least one first group if the defect cannot be detected by surface-sensitive measurements, if the defect exceeds a predefined size and/or if different measurement methods when determining a position of the defect produce different results.

11. The method as claimed in claim 10, wherein step a. comprises: classifying the defects of the mask blank not mentioned in the preceding claim into the at least one second group.

12. The method as claimed in claim 1, wherein the priority includes: an outlay for repairing a defect of the second group, and/or a risk when repairing a defect of the second group, and/or a complexity when repairing a defect of the second group and/or the effective defect size of a defect of the second group.

13. The method as claimed in claim 1, furthermore comprising the step of: allocating at least one defect with high priority to the at least one first group before performing step c.

14. The method as claimed in claim 13, furthermore comprising: repeating the process of allocating at least one defect with high priority to the at least one first group as long as all defects of the first group of defects can be compensated for by optimizing the arrangement of the absorber pattern.

15. The method as claimed in claim 1, furthermore comprising the step of: dividing the process of at least partly repairing the second group into two substeps, wherein the first substep is carried out before the process of compensating for the defects of the first group.

16. A mask for the extreme ultraviolet wavelength range which is produced according to a method in claim 1.

17. A device for treating defects of a mask blank for the extreme ultraviolet wavelength range, comprising:
a. means for classifying the defects into at least one first group and one second group;
b. means for allocating a priority to the defects of the at least one second group;
c. means for optimizing the arrangement of an absorber pattern on the mask blank in order to compensate for a maximum number of the defects of the first group by use of the arranged absorber pattern; and
d. means for applying the optimized absorber pattern to the mask blank.

18. The device as claimed in claim 17, wherein the means for classifying the defects and the means for optimizing the arrangement of an absorber pattern comprise at least one computing unit.

19. The device as claimed in claim 17 furthermore comprising means for at least partly repairing the defects of the second group.

20. The device as claimed in claim 19, wherein the means for at least partly repairing the defects of the second group comprise at least one scanning particle microscope and at least one gas feed for locally providing a precursor gas in a vacuum chamber.

21. The device as claimed in claim 17, furthermore comprising means for characterizing the defects of a mask blank, wherein the means for characterizing comprise a scanning particle microscope, an X-ray beam apparatus and/or a scanning probe microscope.

22. A computer program comprising instructions for carrying out all the steps of a method as claimed in claim 1.
